(19) United States
(12) Patent Application Publication
(10) Pub. No.: US 2013/0201639 A1
(43) Pub. Date: Aug. 8, 2013

(54) DISPLAY DEVICE AND METHOD OF MANUFACTURING THE SAME

(71) Applicants: Do hyung RYU, Yongin-City (KR); Hae goo JUNG, Yongin-City (KR)

(72) Inventors: Do hyung RYU, Yongin-City (KR); Hae goo JUNG, Yongin-City (KR)

(21) Appl. No.: 13/709,409

(22) Filed: Dec. 10, 2012

(30) Foreign Application Priority Data
Feb. 2, 2012 (KR) 10-2012-0010935

(51) Int. Cl. H05K 13/00; H05K 1/02

(52) U.S. Cl. CPC H05K 13/0015; H05K 1/0277
USPC 361/749; 156/64

(57) ABSTRACT

A method of manufacturing a display device includes providing a display panel including a first alignment mark on one side of opposite facing sides, obtaining location information of the first alignment mark by imaging the one side of the display panel, providing a flexible printed circuit board that includes a second alignment mark and a subsidiary mark on one side of the flexible printed circuit board, the subsidiary mark being spaced apart from the display panel and being spaced a predetermined distance apart from the second alignment mark, aligning the first alignment mark and the second alignment mark by disposing the subsidiary mark to be spaced the predetermined distance apart from the first alignment mark on the basis of the location information of the first alignment mark, and bonding the display panel and the flexible printed circuit board.

### CROSS-REFERENCE TO RELATED APPLICATIONS

This U.S. non-provisional patent application claims priority under 35 U.S.C. §119 of Korean Patent Application No. 10-2012-0010935, filed on Feb. 2, 2012, the entire contents of which are hereby incorporated by reference.

### BACKGROUND

Embodiments herein relate to display device and method of manufacturing the same, and more particularly, to a display device in which a display panel and a flexible printed circuit board are bonded and a method of manufacturing the same.

A display device includes a display panel displaying a video and a drive printed circuit board driving the display panel. The drive printed circuit board may be electrically connected to the display panel by a flexible printed circuit board.

A first bonding area may be defined in the display panel and a second bonding area may be defined in the flexible printed circuit board. The display panel and the flexible printed circuit board may be bonded in the first and second bonding areas by an anisotropic conductive film (ACF) provided between the first and second bonding areas.

### SUMMARY

According to an embodiment, there is provided a method of manufacturing a display device including providing a display panel including opposite facing sides and a first alignment mark on one side of the opposite facing sides, obtaining location information of the first alignment mark by imaging the one side of the display panel, providing a flexible printed circuit board that includes a second alignment mark and a subsidiary mark on one side of the flexible printed circuit board, the one side of the flexible printed circuit board facing in an opposite direction from the one side of the display panel, on a plane, the subsidiary mark being spaced apart from the display panel and the second alignment mark and the subsidiary mark being spaced a predetermined distance apart from each other in a first direction, aligning the first alignment mark and the second alignment mark by disposing the subsidiary mark to be spaced the predetermined distance apart from the first alignment mark on the basis of the location information of the first alignment mark, and bonding the display panel and the flexible printed circuit board in which the first and second alignment marks are aligned.

The method may further include obtaining location information of the subsidiary mark by imaging the one side of the flexible printed circuit board.

The location information of the first alignment mark may be still image data and the location information of the subsidiary mark is real time video data.

The method may further include displaying the location information of the first alignment mark on an alignment monitor, after obtaining the location information of the first alignment mark.

The method may further include overlapping the location information of the first alignment mark displayed on the alignment monitor and the location information of the subsidiary mark by displaying the location information of the subsidiary mark on the alignment monitor, after obtaining the location information of the subsidiary mark.

The flexible printed circuit board may be made of a semitransparent or opaque material.

The flexible printed circuit board may be a chip on film.

The method may further include a polarizing plate on another one of the opposite facing sides of the display panel, the another one of the opposite facing sides being opposite the one side of the display panel.

The polarizing plate may have a phase difference of ¼ wavelength.

A black pattern covering at least the first alignment mark may be on another one of the opposite facing sides of the display panel, the another one of the opposite facing sides being opposite the one side of the display panel.

The display panel may include a base substrate and a display layer, the display layer being disposed on the base substrate to display an image, and the base substrate being made of an opaque material.

The method may further include disposing an anisotropic conductive film ACF on the one side of the display panel covering the first alignment mark.

The bonding of the display panel and the flexible printed circuit board may compress the display panel and the flexible printed circuit board with the anisotropic conductive film therebetween.

The bonding of the display panel and the flexible printed circuit board may include pre-compressing the display panel and the flexible printed circuit substrate, and main-compressing the display panel and the flexible printed circuit board to electrically connect the display panel and the flexible printed circuit board through the anisotropic conductive film.

According to an embodiment, there is provided a display device including a display panel including opposite facing sides and a first alignment mark on one side of the opposite facing sides, a flexible printed circuit board that includes a subsidiary mark on one side of the flexible printed circuit board, the one side of the flexible printed circuit board facing in an opposite direction from the one side of the display panel, and on a plane, the subsidiary mark being spaced apart from the display panel, an anisotropic conductive film between the display panel and the flexible printed circuit board, the anisotropic conductive film electrically connecting the display panel and the flexible printed circuit board, and a drive printed circuit board connected to the flexible printed circuit board.

A second alignment mark overlapping the first alignment mark on the plane may be on the one side of the flexible printed circuit board.

The display device may further include a polarizing plate on another one of the opposite facing sides of the display panel, the another one of the opposite facing sides being opposite the one side of the display panel.

The polarizing plate may have a phase difference of ¼ wavelength.

A black pattern may cover at least the first and second alignment marks on another one of the opposite facing sides of the display panel, the another one of the opposite facing sides being opposite the one side of the display panel.

The display panel may include a base substrate and a display layer, the display layer being on the base substrate to display an image, and the base substrate being made of opaque material.

### BRIEF DESCRIPTION OF THE FIGURES

Preferred embodiments will be described below in more detail with reference to the accompanying drawings. The embodiments may, however, be embodied in different forms and should not be constructed as limited to the embodiments set forth herein. Rather, these embodiments are provided so that this disclosure will be thorough and complete, and will fully convey the scope to those skilled in the art. Like numbers refer to like elements throughout.

FIG. 1A is a top plan view of display device in accordance with an embodiment.

FIG. 1B is a cross sectional view taken along the line I-I′ of FIG. 1A.

FIG. 2 is a flow chart showing a method of manufacturing a display device in accordance with an embodiment.

FIG. 3 is a perspective view for describing S2 of FIG. 2.

FIG. 4 is perspective view for describing S5 of FIG. 2.

FIG. 5A is a drawing illustrating an alignment monitor of before a first alignment mark and a second alignment mark are not aligned.

FIG. 5B is a drawing illustrating an align monitor of after a first alignment mark and a second alignment mark are not aligned.

FIG. 6 is a cross sectional view of display device in accordance with another embodiment.

FIG. 7 is a cross sectional view of display device in accordance with still another embodiment.

### DETAILED DESCRIPTION

Embodiments will be described more fully hereinafter with reference to the accompanying drawings, in which embodiments of the invention are shown. These may, however, be embodied in many different forms and should not be construed as limited to the embodiments set forth herein. Rather, these embodiments are provided so that this disclosure will be thorough and complete, and will fully convey the scope to those skilled in the art. In the drawings, the size and relative sizes of layers and regions may be exaggerated for clarity. Like numbers refer to like elements throughout.

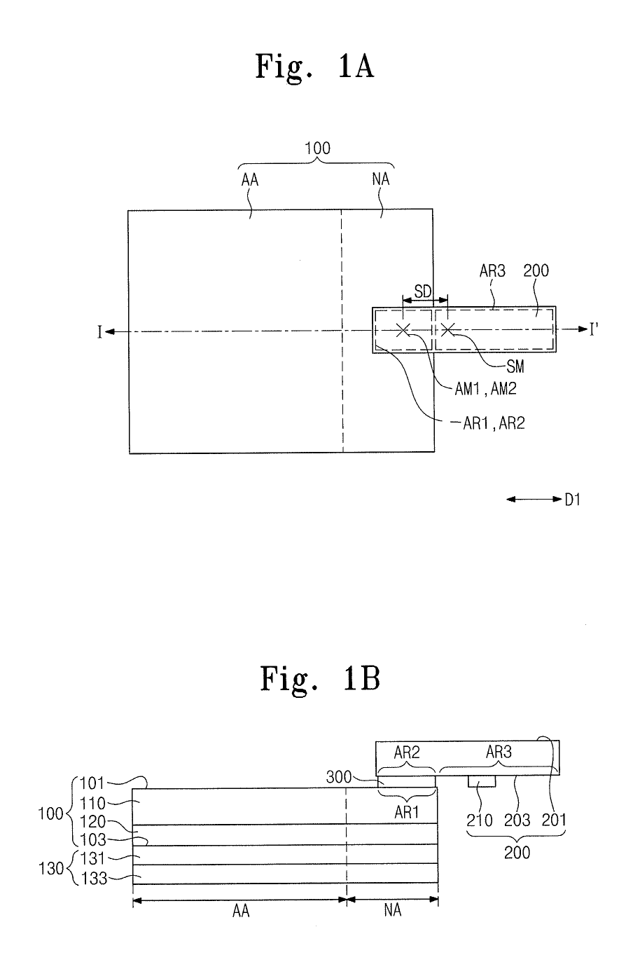

FIG. 1A is a top plan view of display device in accordance with an embodiment. FIG. 1B is a cross sectional view taken along the line I-I′ of FIG. 1A.

Referring to FIGS. 1A and 1B, the display device includes a display panel 100, a polarizing plate 130, a flexible printed circuit board 200, an anisotropic conductive film 300 and a drive printed circuit board (not shown).

Various display panels, such as a liquid crystal display panel (LCD panel), an electrophoretic display panel (EDP), an organic light-emitting display panel (OLED panel) or a plasma display panel (PDP), may be used as the display panel 100. In the present embodiment, the organic light-emitting display panel is used as the display panel 100.

The display panel 100 includes a base substrate 110 and a display layer 120 disposed on the base substrate 110.

The base substrate 110 may include a plurality of pixel areas. The base substrate 110 may be made of transparent material. A light that enters the base substrate 110 may penetrate the base substrate 110.

A gate line (not shown), a data line (not shown) disposed to cross the gate line, a thin film transistor (not shown) which is disposed in each pixel area and is turned on by a gate on-voltage provided from the gate line and outputs a data voltage provided from the data lines, a pixel electrode (not shown) to which the data voltage provided from the thin film transistor is applied, and an organic light-emitting display disposed to correspond to the pixel electrode may be disposed in the display layer. The organic light-emitting display may receive the data voltage from the pixel electrode to display a video corresponding to the data voltage.

The display panel includes a top surface 101 and a bottom surface 103, which is on an opposite side of the display panel from the top surface 101. Also, the display panel 100 includes a display area AA displaying a video and a non-display area NA adjacent to at least a part of the display area AA.

A first bonding area AR1 may be defined on one side of the top surface 101. On a plane, the first bonding area AR1 may overlap at least a part of the non-display area NA.

Although not illustrated in the drawing, interconnection lines providing an electrical signal to the gate line and the data line may be disposed in the first bonding area AR1.

The first bonding area AR1 includes a first alignment mark AM1. In an embodiment, the display panel 100 in which one first bonding area AR1 is defined is illustrated. However, in other implementations, a plurality of bonding areas AR1 may be defined in the display panel 100 and the first alignment mark may be included in each of the first bonding areas.

The polarizing plate 130 is provided onto the bottom surface 103 of the display panel 100. Light that enters toward the display panel 100 from a lower portion of the polarizing plate 130 to penetrate the polarizing plate 130 and be reflected at an internal interface of the display panel 100 cannot penetrate the polarizing plate 130 again. That is, an external light which enters the polarizing plate 130 by the polarizing plate 130 may be blocked out.

If the polarizing plate 130 has a function of blocking out an external light, the polarizing plate 130 may be formed of a single layer or a multi layer.

The polarizing plate 130 may include a first polarizing plate 131 and a second polarizing plate 133.

The first polarizing plate 131 is provided on the bottom surface of the display panel 100. The first polarizing plate 131 may be a circularly polarizing plate having a phase difference of ¼ wavelength.

The second polarizing plate 133 is opposite the bottom surface 103 of the display panel 100 with the first polarizing plate 131 therebetween. The second polarizing plate 133 may be a linearly polarizing plate having a phase difference of ½ wavelength. A penetration axis of the second polarizing plate 133 may be an x axis or a y axis. Hereinafter, it is assumed that the penetration axis of the second polarizing plate 133 is an x axis.

An effect of blocking out an external light of the polarizing plate 130 is described. Light (hereinafter, external light) entering toward the display panel 100 from a lower portion of the polarizing plate 130 passes through the second polarizing plate 133. The light that has passed through the second polarizing plate 133 is linearly polarized in an x-axis direction. The light that is linearly polarized in an x-axis direction is circularly-polarized (e.g., left turn circular polarization) while passing through the first polarizing plate 131. A part of the light that is circularly-polarized is reflected at an internal interface of the display panel 100 to be right turn circularly polarized. The light that is right turn circularly polarized is linearly-polarized in the y axis crossing the x axis while passing through the first polarizing plate 131 again. The light that is linearly polarized in the y axis cannot pass through the second polarizing plate 133 and is absorbed into the second polarizing plate 133. That is, the external light is blocked out by the polarizing plate 130.

Thus, when a worker looks at the display panel 100 toward an upper portion of the display panel 100 from a lower portion of the display panel 100 with eyes or with an optical camera, the worker cannot recognize the first alignment mark AM1.

The flexible printed circuit board 200 may be a chip on film (COF). A drive chip 210 may be disposed on one side of the flexible printed circuit board 200.

The flexible printed circuit board 200 may include a top surface 201 and a bottom surface 203 that is on an opposite side of the flexible printed circuit board 200 from the top surface 201.

On the bottom surface 203, the second bonding area AR2 and a subsidiary area AR3 adjacent to the second bonding area AR2 are defined. The second bonding area AR2 is disposed to overlap the first bonding area AR1 on the plane. A second alignment mark AM2 is included in the second bonding area AR2. The second alignment mark AM2 is disposed to overlap the first alignment mark AM1 on the plane.

A subsidiary mark SM is included in the subsidiary area AR3. The subsidiary mark SM may be spaced a standard or predetermined distance SD apart from the second alignment mark AM3 in a first direction D1. In FIG. 1A, the first direction D1 is illustrated to be a horizontal (x axis) direction on the plane. However, if the subsidiary mark SM is within the subsidiary area AR3, the first direction D1 may be any direction. Similarly, if the subsidiary mark SM is within the subsidiary area AR3, the standard distance SD may be any distance. On the plane, the subsidiary mark SM is spaced apart from the display panel 100.

The flexible printed circuit board 200 may be made of a semitransparent or opaque material. Thus, although a worker looks at the flexible printed circuit board 200 toward a lower portion of the flexible printed circuit board 200 from an upper portion of the flexible printed circuit board 200 with eyes or an optical camera, the worker cannot recognize the second alignment mark AM2 and the subsidiary mark SM.

The first bonding area AR1 and the second bonding area AR2 may be accurately aligned on the basis of the subsidiary mark SM, as discussed below.

The anisotropic conductive film (ACF) 300 is provided between the display panel 100 and the flexible printed circuit board 200 to electrically connect the display panel 100 and the flexible printed circuit board 200 in the first bonding area AR1 and the second bonding area AR2.

The drive printed circuit board (not shown) may be connected to one side of the flexible printed circuit board 200. The drive printed circuit board may be disposed to be spaced apart from the display panel 100. The drive printed circuit board provides an electrical signal driving the display panel 100 to the display panel 100 through the flexible printed circuit board 200. An electrical signal output from the drive printed circuit board may be transmitted to the first bonding area AR1 of the display panel 100 through the anisotropic conductive film 300 from the second bonding area AR2 of the flexible printed circuit board AR2. The display panel 100 can display an image by the electrical signal.

Hereinafter, a method of manufacturing a display device in accordance with an embodiment is described. Constituent elements of the display device are substantially the same as the constituent elements of the display device illustrated in FIGS. 1A and 1B, and description thereof will not be repeated. The method of manufacturing a display device will be described in detail.

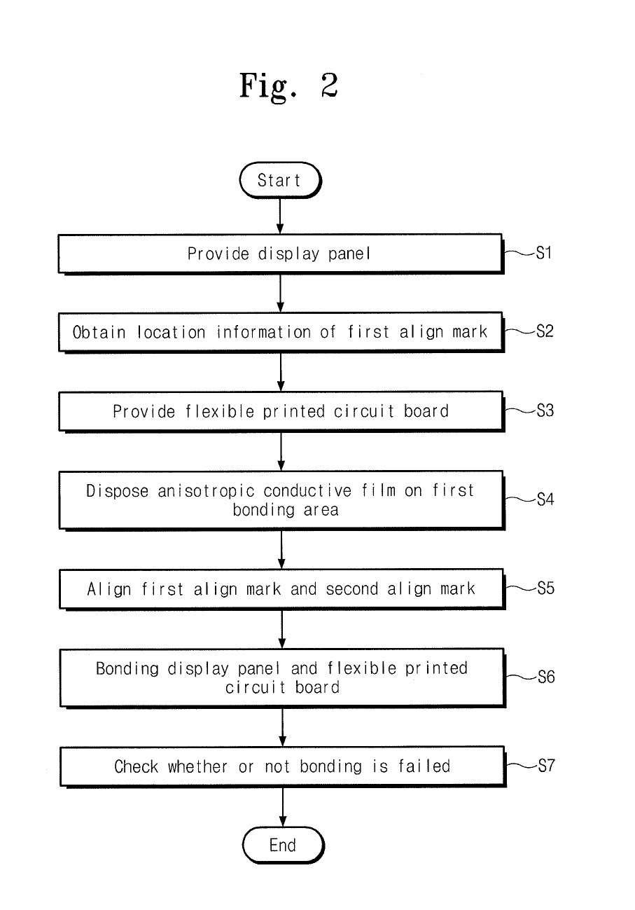

FIG. 2 is a flow chart showing a method of manufacturing a display device in accordance with an embodiment.

Referring to FIGS. 1A, 1B and 2, the display device is manufactured through following processes.

The display panel 100 is provided (S1). The display panel 100 includes the top surface 101 and the bottom surface 103 which is on an opposite side of the display panel 100 from the top surface 101. The first bonding area AR1 is defined on the top surface 101 of the display panel 100, and the first alignment mark AM1 is included in the first bonding area AR1.

The top surface 101 of the display panel 100 is filmed or imaged to obtain location information of the first alignment mark AM1 (S2).

The flexible printed circuit board 200 is provided (S3). The flexible printed circuit board 200 includes the second bonding area AR2 and the subsidiary area AR3 adjacent to the second bonding area AR2 on the bottom surface 103, which is on an opposite side of the flexible printed circuit board 200 from the top surface 101. The second alignment mark AM2 is included in the second bonding area AR2, and the subsidiary mark SM is included in the subsidiary area AR3. The second alignment mark AM2 and the subsidiary mark SM are spaced a standard or predetermined distance apart from each other in the first direction. On the plane, the subsidiary mark SM is spaced apart from the display panel 100.

The anisotropic conductive film ACF is disposed on the first bonding area AR1 (S4).

On the basis of location information of the first alignment mark AM1, the subsidiary mark SM is disposed to be spaced the standard distance SD apart from the first alignment mark AM1 to align the first alignment mark AM1 and the second alignment mark AM2 (S5).

The display panel 100 and the flexible printed circuit board 200 are bonded (S6). In a state that the first alignment mark SM1 and the second alignment mark SM2 are aligned, the display panel 100 and the flexible printed circuit board 200 are compressed with the anisotropic conductive film 300 therebetween to be bonded to each other. First, the display panel 100 and the flexible printed circuit board 200 may be pre-compressed. After that, the display panel 100 and the flexible printed circuit board 200 may be main-compressed and then the display panel 100 and the flexible printed circuit board 200 are electrically connected to each other through the anisotropic conductive film 300.

In addition, whether the bonding has failed or not may be checked (S7). Checking whether the bonding has failed or not may be done by measuring a connection resistance of the first and second bonding areas AR1 and AR2 or may be done by testing whether the manufactured display device is driven or not. Checking whether the bonding has failed or not may be omitted.

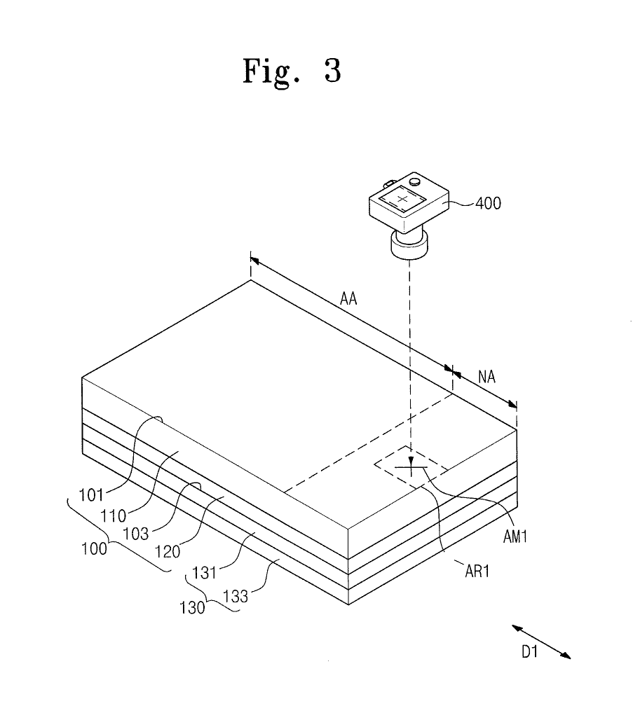

FIG. 3 is a perspective view for describing S2 of FIG. 2.

A worker films the first bonding area AR1 using a first optical camera 400 provided above the top surface 101 of the display panel 100 and obtains location information of the first alignment mark AM1. The location information of the first alignment mark AM1 may be still image data.

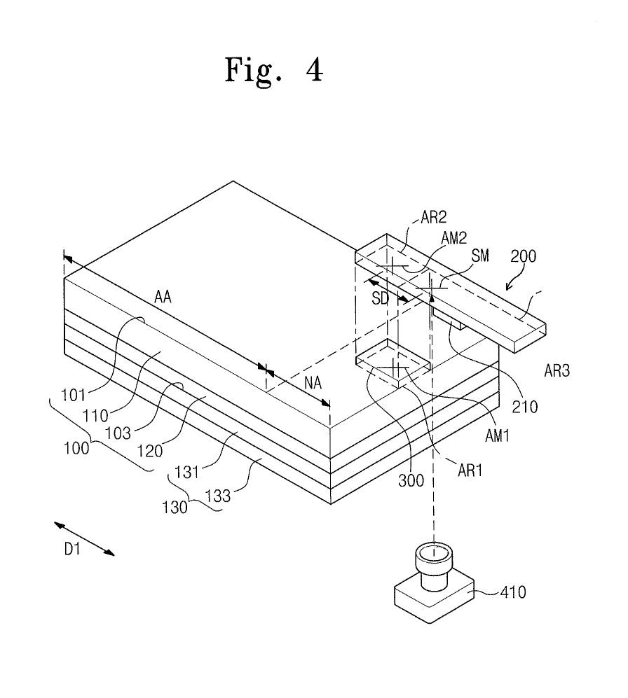

FIG. 4 is perspective view for describing S5 of FIG. 2.

The polarizing plate 130 is provided on the bottom surface 103 of the display panel 100. The polarizing plate 130 may include the first polarizing plate 131 having a phase difference of ¼ wavelength and the second polarizing plate 133 having a phase difference of ½ wavelength.

Thus, although a worker looks at the display panel 100 toward an upper portion of the display panel 100 from a lower portion of the display panel 100 with eyes or an optical camera, the worker cannot recognize the first alignment mark AM1 and the second alignment mark AM2.

The worker films the subsidiary mark SM using a second optical camera 410 provided below the bottom surface of the display panel 100 and the flexible printed circuit board 200 and obtains location information of the subsidiary mark SM. The location information of the subsidiary mark SM is real time video data. The subsidiary mark SM and the second alignment mark AM2 may be disposed to be spaced the standard distance SD apart from each other in the first direction D1. Accordingly, a location of the second alignment mark AM2 may be drawn from the location information of the subsidiary mark SM.

On the basis of location information of the first alignment mark AM1, the subsidiary mark SM is disposed to be spaced the standard distance SD apart from the first alignment mark AM1 in the first direction D1 to align the first alignment mark AM1 and the second alignment mark AM2.

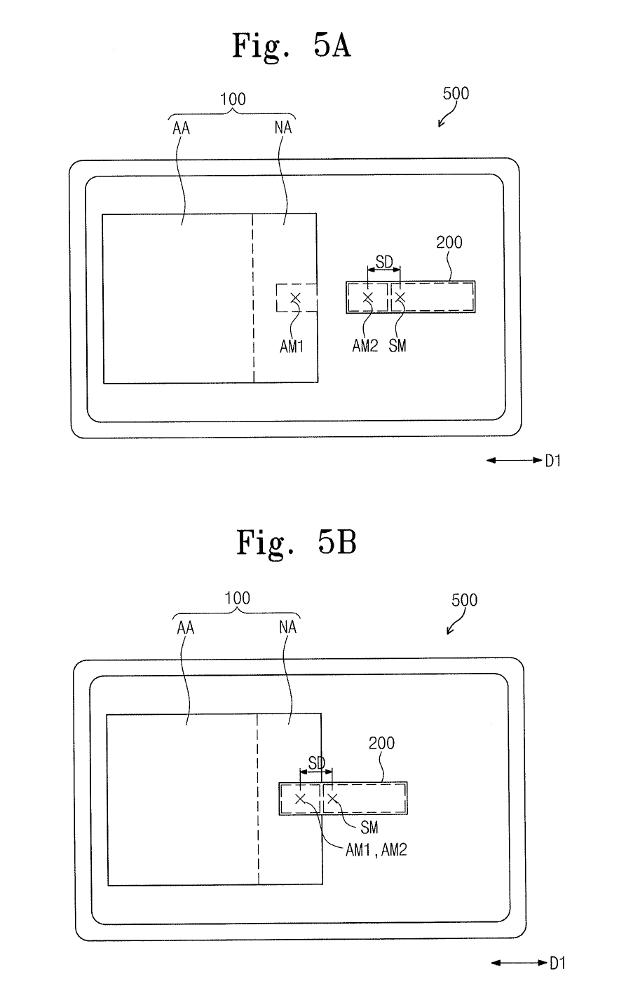

FIG. 5A is a drawing illustrating an alignment monitor showing a relationship before the first alignment mark and the second alignment mark are aligned. FIG. 5B is a drawing illustrating an alignment monitor showing a relationship after the first alignment mark and the second alignment mark have been aligned.

Referring to FIGS. 5A and 5B, the obtained location information of the first alignment mark AM1 is transmitted to an alignment monitor 500. The alignment monitor 500 displays location information of the first alignment mark AM1.

The obtained location information of the subsidiary mark SM is transmitted to an alignment monitor 500. The alignment monitor 500 displays the location information of the subsidiary mark SM to overlap the location information of the subsidiary mark SM and the location information of the first alignment mark AM1 displayed on the alignment monitor 500.

The subsidiary mark SM may be disposed to be spaced the standard distance SD apart from the first alignment mark AM1 displayed on the alignment monitor 500 in the first direction D1 to align the first alignment mark AM1 and the second alignment mark AM2.

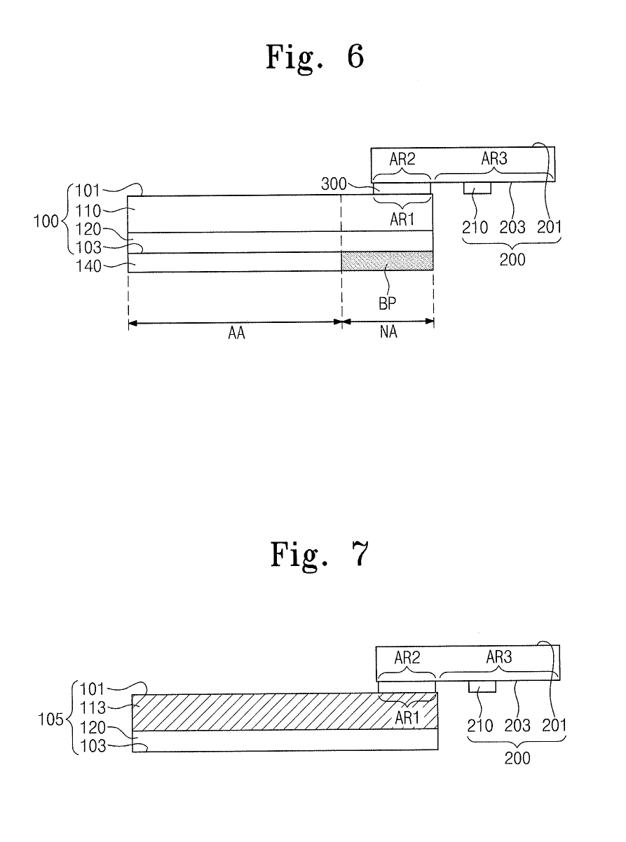

FIG. 6 is a cross sectional view of display device in accordance with another embodiment.

The display device illustrated in FIG. 6 has the same structure as the display device illustrated in FIGS. 1A and 1B except for including a black patterned film (BPF) 140 instead of the polarizing plate 130. Thus, the black patterned film (BPF) 140 is described herein in detail and a description of the remaining constituent elements is not repeated.

Referring to FIGS. 1A and 6, the black patterned film (BPF) 140 may be provided on the bottom surface 103 of the display panel 100. The black patterned film (BPF) 140 may have a black pattern BP formed to cover at least first alignment mark AM1. The black pattern BP is formed to correspond to the non-display area NA of the display panel 100, so that the inside of the non-display area of the display panel 100 is not seen.

Thus, although a worker looks at the display panel 100 toward an upper portion of the display panel 100 from a lower portion of the display panel 100 with eyes or an optical camera, since the black pattern BP covers the first alignment mark, the worker cannot recognize the first alignment mark AM1.

A method of manufacturing the display device illustrated in FIG. 6 is the same with the method of manufacturing the display device illustrated in FIGS. 1A and 1B, except that the black pattern film 140 is provided on the bottom surface 103 of the display panel 100. Thus, further description is not repeated.

FIG. 7 is a cross sectional view of display device in accordance with still another embodiment.

The display device illustrated in FIG. 7 has the same structure as the display device illustrated in FIGS. 1A and 1B except that the polarizing plate is omitted, and the material forming the base substrate is different. Thus, hereinafter, the base substrate 113 is described in detail and a description of the remaining constituent elements is not repeated.

Referring to FIGS. 1A and 7, the base substrate 113 may be formed from an opaque material. The base substrate 113 may be formed of a plurality of layers and a part of the plurality of layers may be formed from an opaque material. The base substrate 113 may be made of a double layer including an opaque metallic layer and an insulating layer.

Thus, although a worker looks at the display panel 105 toward an upper portion of the display panel 105 from a lower portion of the display panel 105 with eyes or an optical camera, since the base substrate 113 is opaque, the worker cannot recognize the first alignment mark AM1.

A method of manufacturing the display device illustrated in FIG. 7 may be the same as the method of manufacturing the display device illustrated in FIGS. 1A and 1B except that the display panel 105 including the base substrate 113 made of an opaque material is provided and the polarizing plate is omitted. Thus, further description is not repeated.

By way of summation and review, in electrically connecting a drive printed circuit board to a display panel through a flexible printed circuit board, a first bonding area may be defined in the display panel and a second bonding area may be defined in the flexible printed circuit board. The display panel and the flexible printed circuit board may be bonded in the first and second bonding areas by an anisotropic conductive film (ACF) provided between the first and second bonding areas.

To bond the display panel and the flexible printed circuit board, the first and second bonding areas may be imaged using an optical camera in order to accurately align the first bonding area and the second bonding area. However, if a round polarizing plate or a black pattern film is disposed in one side of the display panel, or if a base substrate of the display panel is made of opaque material, it may not be possible to image the first and second bonding areas using an optical camera. Accordingly, a worker may not be able to accurately align the first and second bonding areas. In contrast, according to a display device in accordance with an embodiment a first bonding area of opaque display panel and a second bonding area of flexible printed circuit board may be accurately aligned, so that the display panel and the flexible printed circuit board may be bonded. Also, a method of manufacturing the display device is provided.

The above-disclosed subject matter is to be considered illustrative, and not restrictive, and the appended claims are intended to cover all such modifications, enhancements, and other embodiments, which fall within the true spirit and scope. Thus, to the maximum extent allowed by law, the scope is to be determined by the broadest permissible interpretation of the following claims and their equivalents, and shall not be restricted or limited by the foregoing detailed description.

What is claimed is:

1. A method of manufacturing a display device comprising:
providing a display panel including opposite facing sides and a first alignment mark on one side of the opposite facing sides;
obtaining location information of the first alignment mark by imaging the one side of the display panel;
providing a flexible printed circuit board that includes a second alignment mark and a subsidiary mark on one side of the flexible printed circuit board, the one side of the flexible printed circuit board facing in an opposite direction from the one side of the display panel, on a plane, the subsidiary mark being spaced apart from the display panel and the second alignment mark and the subsidiary mark being spaced a predetermined distance apart from each other in a first direction;
aligning the first alignment mark and the second alignment mark by disposing the subsidiary mark to be spaced the predetermined distance apart from the first alignment mark on the basis of the location information of the first alignment mark; and
bonding the display panel and the flexible printed circuit board in which the first and second alignment marks are aligned.

2. The method as claimed in claim 1, further comprising obtaining location information of the subsidiary mark by imaging the one side of the flexible printed circuit board.

3. The method as claimed in claim 2, wherein the location information of the first alignment mark is still image data and the location information of the subsidiary mark is real time video data.

4. The method as claimed in claim 3, further comprising, after obtaining the location information of the first alignment mark, displaying the location information of the first alignment mark on an alignment monitor.

5. The method as claimed in claim 4, further comprising, after obtaining the location information of the subsidiary mark, overlapping the location information of the first alignment mark displayed on the alignment monitor and the location information of the subsidiary mark by displaying the location information of the subsidiary mark on the alignment monitor.

6. The method as claimed in claim 1, wherein the flexible printed circuit board is made of a semitransparent or opaque material.

7. The method as claimed in claim 6, wherein the flexible printed circuit board is a chip on film.

8. The method as claimed in claim 1, further comprising a polarizing plate on another one of the opposite facing sides of the display panel, the another one of the opposite facing sides being opposite the one side of the display panel.

9. The method as claimed in claim 8, wherein the polarizing plate has a phase difference of ¼ wavelength.

10. The method as claimed in claim 1, wherein a black pattern covering at least the first alignment mark is on another one of the opposite facing sides of the display panel, the another one of the opposite facing sides being opposite the one side of the display panel.

11. The method as claimed in claim 1, wherein the display panel includes a base substrate and a display layer, the display layer being disposed on the base substrate to display an image, and the base substrate being made of an opaque material.

12. The method as claimed in claim 1, further comprising disposing an anisotropic conductive film on the one side of the display panel covering the first alignment mark.

13. The method as claimed in claim 12, wherein the bonding of the display panel and the flexible printed circuit board compresses the display panel and the flexible printed circuit board with the anisotropic conductive film therebetween.

14. The method as claimed in claim 13, wherein the bonding of the display panel and the flexible printed circuit board includes;
pre-compressing the display panel and the flexible printed circuit substrate; and
main-compressing the display panel and the flexible printed circuit board to electrically connect the display panel and the flexible printed circuit board through the anisotropic conductive film.

15. A display device comprising:
a display panel including opposite facing sides and a first alignment mark on one side of the opposite facing sides;
a flexible printed circuit board that includes a subsidiary mark on one side of the flexible printed circuit board, the one side of the flexible printed circuit board facing in an opposite direction from the one side of the display panel, and on a plane, the subsidiary mark being spaced apart from the display panel;
an anisotropic conductive film between the display panel and the flexible printed circuit board, the anisotropic conductive film electrically connecting the display panel and the flexible printed circuit board; and
a drive printed circuit board connected to the flexible printed circuit board.

16. The display device as claimed in claim 15, wherein a second alignment mark overlapping the first alignment mark on the plane is on the one side of the flexible printed circuit board.

17. The display device as claimed in claim 16, further comprising a polarizing plate on another one of the opposite facing sides of the display panel, the another one of the opposite facing sides being opposite the one side of the display panel.

18. The display device as claimed in claim 17, wherein the polarizing plate has a phase difference of ¼ wavelength.

19. The display device as claimed in claim 16, wherein a black pattern covers at least the first and second alignment marks on another one of the opposite facing sides of the display panel, the another one of the opposite facing sides being opposite the one side of the display panel.

20. The display device as claimed in claim 16, wherein the display panel includes a base substrate and a display layer, the display layer being on the base substrate to display an image, and the base substrate being made of an opaque material.
